(19) United States
(12) Patent Application Publication
(10) Pub. No.: US 2012/0180475 A1
(43) Pub. Date: Jul. 19, 2012

(54) ACTUATOR AND SHEET-SHAPED ACTUATOR

(75) Inventors: Masahiro Shimizu, Nirasaki-shi (JP); Shigekazu Komatsu, Nirasaki (JP); Eiichi Nishimura, Nirasaki (JP); Yoshio Kimura, Koshi (JP); Takahiko Ooasa, Nirasaki (JP); Hidenori Okuzaki, Kofu (JP)

(73) Assignees: UNIVERSITY OF YAMANASHI, Kofu-shi, Yamanashi (JP); TOKYO ELECTRON LIMITED, Tokyo (JP)

(21) Appl. No.: 13/387,188

(22) PCT Filed: Sep. 28, 2010
(86) PCT No.: PCT/JP2010/066802

§ 371 Date: Mar. 14, 2012

(30) Foreign Application Priority Data
Oct. 9, 2009 (JP) 2009-235436

(51) Int. Cl. F15B 21/06

(52) U.S. Cl. 60/530

(57) ABSTRACT

An actuator 10 includes a main body 14 having a displacement unit 11 and electrodes 12 and 13 configured to apply a voltage to the displacement unit 11, the displacement unit being made of a mixture of a silicone-containing elastomer and an ionic liquid, and being displaced by applying a voltage between the electrodes; and a displacement transmission unit 15 configured to be displaced in an out-of-plane direction by displacement of the displacement unit 11.

### TECHNICAL FIELD

The present disclosure relates to an actuator and a sheet-shaped actuator using the same.

### BACKGROUND ART

In manufacturing semiconductor devices, various processes such as formation of a poly silicon film or a metal film, formation of a pattern by means of photolithography, etching, and testing of electrical characteristics with a probe device have been performed onto a semiconductor wafer.

For the sake of improvement in productivity, a diameter of a semiconductor wafer has become scaled up to a diameter of about 450 mm. Further, a semiconductor device has been required to be miniaturized. In order for the semiconductor device to be miniaturized, it is necessary to perform a uniform process onto the semiconductor wafer. However, as the diameter of the semiconductor wafer increases, the semiconductor wafer becomes easily deformed by being bent. Thus, a flat surface of the semiconductor wafer cannot be obtained easily. Accordingly, it is difficult to perform a uniform process.

In view of the foregoing description, it can be developed to provide an actuator that corrects deformation of a semiconductor wafer or follows such deformation at, for example, a mounting table for mounting thereon the semiconductor wafer.

Further, in a semiconductor device manufacturing apparatus, it is required to use a small-sized actuator so as to adjust a height or a pressure of a component.

Conventionally, a small-sized actuator has used a small motor. However, such a small-sized actuator is not sufficiently small enough for the use described above. Although there is developed an actuator made of piezoelectric ceramic as a miniaturized actuator, the actuator does not have sufficient stroke.

Furthermore, there is developed an actuator made of organic materials (see Japanese Patent Laid-open Publication No. 2008-228542, Japanese Patent Laid-open Publication No. 2008-252958, and Japanese Patent Laid-open Publication No. 2009-033944). However, this is limited in use, and, thus, it is not suitable for the use described above.

### DISCLOSURE OF THE INVENTION

### Problems to Be Solved by the Invention

The present disclosure provides an actuator which is capable of being miniaturized and having a great amount of stroke, but is not limited in use.

Further, the present disclosure provides a sheet-shaped actuator capable of correcting deformation of a substrate, following the deformation of the substrate when the substrate is supported, or adjusting a position of a component.

### Means for Solving the Problems

In accordance with one aspect of the present disclosure, there is provided an actuator that includes a main body having a displacement unit and an electrode configured to apply a voltage to the displacement unit, the displacement unit being made of a mixture of a silicone-containing elastomer and an ionic liquid, and being displaced by applying a voltage to the electrode; and a displacement transmission unit configured to be displaced in an out-of-plane direction by displacement of the displacement unit.

In accordance with another aspect of the present disclosure, there is provided a sheet-shaped actuator that includes multiple main bodies each having a displacement unit and an electrode configured to apply a voltage to the displacement unit, the displacement unit being made of a mixture of a silicone-containing elastomer and an ionic liquid, and being displaced by applying a voltage to the electrode; a flat container in which the multiple main bodies are arranged in a planar shape; and a common displacement transmission unit configured to be displaced in an out-of-plane direction by displacement of each displacement unit of the multiple main bodies.

### BRIEF DESCRIPTION OF THE DRAWINGS

FIG. 1 is a schematic cross-sectional view of an actuator in accordance with a first embodiment of the present disclosure.

FIG. 2A is a schematic diagram showing a status of a displacement unit when a voltage is not applied to electrodes of the actuator in accordance with the first embodiment of the present disclosure.

FIG. 2B is a schematic diagram showing a status of a displacement unit when a voltage is applied to electrodes of the actuator in accordance with the first embodiment of the present disclosure.

FIG. 3A is a schematic cross-sectional view of an actuator in accordance with a second embodiment of the present disclosure.

FIG. 3B is a simplified diagram of a displacement unit of the actuator in accordance with the second embodiment of the present disclosure.

FIG. 4 shows a displaced state of the displacement unit of the actuator in accordance with the second embodiment of the present disclosure.

FIG. 5 is a plane view of a sheet-shaped pressure sensor in accordance with a third embodiment of the present disclosure.

FIG. 6 is a cross-sectional view showing a part of the sheet-shaped pressure sensor in accordance with the third embodiment of the present disclosure.

FIG. 7 is a plane view of a sheet-shaped pressure sensor in accordance with a fourth embodiment of the present disclosure.

FIG. 8 is a cross-sectional view showing a part of the sheet-shaped pressure sensor in accordance with the fourth embodiment of the present disclosure.

FIG. 9 is a cross-sectional view of a probe device using an actuator in accordance with the first embodiment or the second embodiment as a load control member.

FIG. 10 is a plane view in a vicinity of an upper surface of a connecting member of the probe device shown in FIG. 9.

FIG. 11 is a graph showing a relationship between positional displacement S of electrode pads and a load F generated as a contact load between contactors and the electrode pads in the probe device shown in FIG. 9.

FIG. 12 is a cross-sectional view of a mounting table of a plasma etching apparatus using a sheet-shaped actuator of the present disclosure as a gap adjustment sheet of a focus ring.

FIG. 13 is a plane view of the sheet-shaped actuator used in the mounting table shown in FIG. 12.

FIG. 14 is a cross-sectional view of a mounting table of a plasma etching apparatus using a sheet-shaped actuator of the present disclosure as a shape correction sheet for correcting a shape of a wafer on the mounting table.

FIG. 15 is a plane view of the sheet-shaped actuator used in the mounting table shown in FIG. 14.

FIG. 16 is a cross-sectional view of a heating unit of a bake apparatus using a sheet-shaped actuator of the present disclosure as a gap adjustment sheet.

FIG. 17 is a plane view of the sheet-shaped actuator used in the heating unit shown in FIG. 16;

FIG. 18A is a plane view of a wafer chuck that employs an actuator of the present disclosure and is used to transfer a wafer in a wafer coating/developing apparatus.

FIG. 18B is a side view of a wafer chuck that employs an actuator of the present disclosure and is used to transfer a wafer in a wafer coating/developing apparatus.

FIG. 19A is a side view of a MEMS pattern wafer chuck employing a sheet-shaped actuator of the present disclosure.

FIG. 19B is a plane view of a sheet-shaped actuator used in a MEMS pattern wafer chuck employing a sheet-shaped actuator of the present disclosure.

FIG. 19C is a plane view of a hole spacer used in a MEMS pattern wafer chuck employing a sheet-shaped actuator of the present disclosure.

FIG. 19D is a cross-sectional view of a chuck part of a MEMS pattern wafer chuck employing a sheet-shaped actuator of the present disclosure.

### BEST MODE FOR CARRYING OUT THE INVENTION

Hereinafter, embodiments of the present disclosure will be described with reference to the accompanying drawings.

### First Embodiment

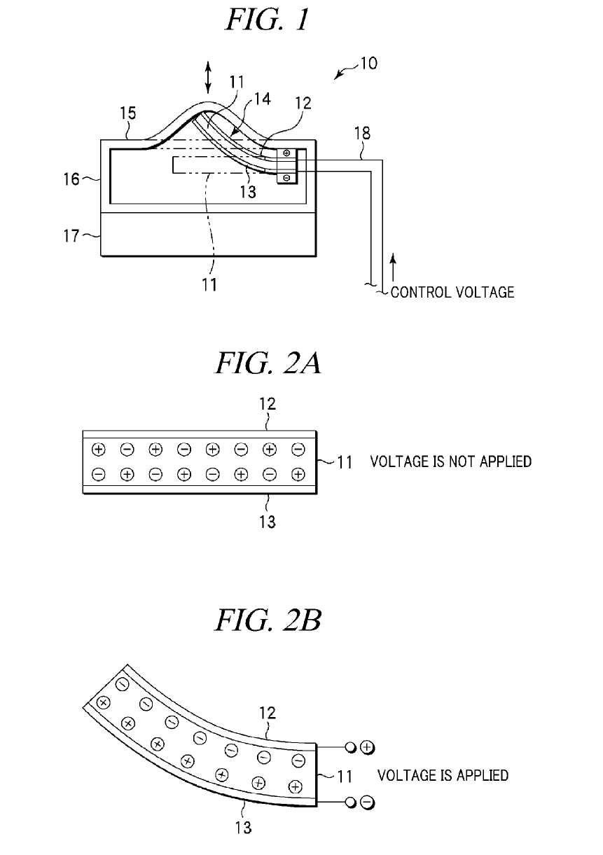

FIG. 1 is a schematic cross-sectional view of an actuator in accordance with a first embodiment of the present disclosure.

As depicted in FIG. 1, an actuator 10 in accordance with the present embodiment includes a main body 14 having a displacement unit 11 and electrodes 12 and 13; and a displacement transmission unit 15. The displacement unit 11 has a plate shape and is made of a mixture of a silicone-containing elastomer as an electrically driven polymer and an ionic liquid. Further, the electrodes 12 and 13 are provided on both surfaces of the displacement unit 11 so as to supply power to the displacement unit 11. The displacement transmission unit 15 is provided so as to cover the displacement unit 11 and displaced in an out-of-plane direction (in a direction perpendicular to a plane) by displacement of the displacement unit 11.

A main surface of the displacement unit 11 is formed in a plate shape in a depth direction of FIG. 1. When a voltage is not applied, the displacement unit 11 is in a horizontal state as indicated by a dashed double-dotted line in FIG. 1. When a control voltage is applied via the electrodes 12 and 13, a front end is displaced to be bent in one direction, e.g. in an upward direction in FIG. 1, as indicated by a solid line. Thus, the displacement transmission unit 15 is displaced in an out-of-plane direction, e.g. in an upward direction in FIG. 1.

The displacement transmission unit 15 is made of resin, such as polyimide, having elasticity. When a voltage is not applied to the displacement unit 11 so that the displacement unit 11 is in a horizontal state, the displacement transmission unit 15 is in a flat state. When a voltage is applied to the displacement unit 11 so that the displacement unit 11 is displaced, the displacement transmission unit 15 is displaced accordingly in an out-of-plane direction, e.g. in an upward direction in FIG. 1. Thereafter, when the voltage is not applied so that the displacement unit 11 returns to its horizontal state, the displacement transmission unit 15 also returns to its flat state. Since particles are hardly generated from the polyimide resin, it may be desirable to make the displacement transmission unit 15 of the polyimide resin.

The displacement transmission unit 15 is configured as a part of a container 16 that accommodates the main body 14. The container 16 is fixed to a fixing plate 17 made of metal such as Cu or Al or a soft material such as resin.

In a pair of the electrodes 12 and 13, one is a positive electrode and the other is a negative electrode. A control wire 18 is connected to these electrodes 12 and 13. The control wire 18 is made of metal such as Cu or Al or conductive resin such as PEDOT/PSS. A certain control voltage is applied to the electrodes 12 and 13 via this control wire 18.

As a silicone-containing elastomer of the displacement unit 11, polydimethylsiloxane produced by making a cross-linking reaction between DVPDMS (α, ω-divinyl-polydimethylsiloxane) and PMHS (poly methyl hydrogen siloxane) may be used.

As an ionic liquid, an imidazolium salt, a piperidinium salt, a pyridinium compound, a pyrrolidinium salt, and the like can be used. Desirably, 1-ethyl-3-methylimidazolium tetrafluoroborate ([EMI][BF4]), 1-butyl-3-methylimidazolium tetrafluoroborate ([BMI][BF4]), 1-hexyl-3-methylimidazolium tetrafluoroborate ([HMI][BF4]), 1-ethyl-3-methylimidazolium2-(2-methoxyethoxy)ethyl sulfate ([EMI][MEES]), 1-ethyl-3-methylimidazolium bis(trifluoromethanesulfonyl)imide ([EMI][TFSI]), and 1-butyl-1-methylpyrrolidinium bis(trifluoromethanesulfonyl)imide ([BMP][TFSI]) can be used.

In addition to the above-described ionic liquids, cyclohexyltrimethylammonium bis(trifluoromethanesulfonyl)imide, methyltri-n-octylammonium bis(trifluoromethanesulfonyl)imide, tetrabutylammonium bromide, tetrabutylammonium chloride, tetrabutylphosphonium bromide, tributyl(2-methoxyethyl)phosphonium bis (trifluoromethanesulfonyl)imide, triethylsulfonium bis(trifluoromethanesulfonyl)imide, 1, 3-dimethylimidazolium chloride, 1,3-dimethylimidazoliumdimethyl phosphate, 1-butyl-2,3-dimethylimidazolium bis(trifluoromethanesulfonyl)imide, 1-butyl-2, 3-dimethylimidazolium chloride, 1-butyl-2,3-dimethylimidazolium hexafluorophosphate, 1-butyl-2, 3-dimethylimidazolium polyethylene glycol hexadecyl ether sulfate-coated lipase, 1-butyl-2,3-dimethylimidazolium tetrafluoroborate), 1-butyl-3-methylimidazolium bis(trifluoromethanesulfonyl)imide, 1-butyl-3-methylimidazolium bromide), 1-butyl-3-methylimidazolium chloride, 1-butyl-3-methylimidazolium hexafluorophosphate, 1-butyl-3-methylimidazolium iodide, 1-butyl-3-methylimidazolium tetrachloroferrate, 1-butyl-3-methylimidazolium trifluoromethanesulfonate, 1-ethyl-2,3-dimethylimidazolium bis(trifluoromethanesulfonyl)imide, 1-ethyl-3-methylimidazolium bromide, 1-ethyl-3-methylimidazolium chloride, 1-ethyl-3-methylimidazolium dicyanamide), 1-ethyl-3-methylimidazolium ethyl sulfate, 1-ethyl-3-methylimidazolium hexafluorophosphate, 1-ethyl-3-methylimidazolium hydrogen sulfate, 1-ethyl-3-methylimidazolium iodide, 1-ethyl-3-methylimidazolium methanesulfonate, 1-ethyl-3-methylimidazolium tetrachloroferrate, 1-ethyl-3-methylimidazolium trifluoromethanesulfonate, 1-hexyl-3-methylimidazolium bromide, 1-hexyl-3-methylimidazolium chloride, 1-hexyl-3-methylimidazolium hexafluorophosphate, 1-methyl-3-n-octylimidazolium bromide, 1-methyl-3-n-octylimidazolium chloride, 1-methyl-3-n-octylimidazolium hexafluorophosphate, 1-methyl-3-propylimidazolium iodide, 1-butyl-1-methylpiperidinium bromide, 1-butyl-3-methylpyridinium bromide, 1-butyl-4-methylpyridinium bromide, 1-butyl-4-methylpyridinium chloride, 1-butyl-4-methylpyridinium hexafluorophosphate, 1-butylpyridinium bromide, 1-butylpyridinium chloride, 1-butylpyridinium hexafluorophosphate, 1-ethyl-3-(hydroxymethyl) pyridinium ethyl sulfate, 1-ethyl-3-methylpyridinium ethyl sulfate, 1-ethylpyridinium bromide, 1-ethylpyridinium chloride, 1-butyl-1-methylpyrrolidinium bromide, and 1-butyl-1-methylpyrrolidinium chloride can be used.

By way of example, in a method of manufacturing this displacement unit 11, the silicone-containing elastomer and the ionic liquid are mixed to produce a mixture such that the ionic liquid contained in the mixture is, for example, about 40 wt %. Then, the mixture is introduced into a desired mold, and then, vacuum deaeration is performed. Thereafter, a heat treatment is performed at, for example, about 150° C. for about 30 minutes and the mold is removed.

Desirably, the electrodes 12 and 13 are made of a flexible material capable of following deformation of the displacement unit 11 and can be formed by means of sputtering, for example, gold. In addition to gold, Al, Cu, Pt, a carbon nanotube, a conductive polymer such as PEDOT/PSS, and silver grease may be used as required.

Hereinafter, there will be explained an operation of the actuator 10 configured as described above.

FIG. 2A shows a status of the displacement unit 11 when a voltage is not applied to the electrodes 12 and 13 and also shows that, in the displacement unit 11, positive ions and negative ions of the ionic liquid are dispersed uniformly in the silicone-containing elastomer. FIG. 2B shows a status of the displacement unit 11 when a voltage is applied to the electrodes 12 and 13, and also shows that the positive ions of the ionic liquid are attracted to the electrode 13 having a negative pole and the negative ions are attracted to the electrode 12 having a positive pole. Therefore, polarization is generated within the ionic liquid. As a result, ions are distributed non-uniformly in the displacement unit 11, so that the displacement unit 11 is deformed to be displaced. If a couple of the displacement units 11 are provided in series in a longitudinal direction of the displacement units 11 and their facing ends at the center are bent upwards, a displacement force can be increased.

Since the actuator 10 of the present embodiment includes the displacement unit 11 made of organic materials, the actuator 10 may be greatly deformed by the application of a voltage. Therefore, the actuator 10 may have a great amount of stroke. Further, since the actuator 10 may have a simple configuration in which the electrodes 12 and 13 are provided on the displacement unit 11, the actuator 10 can be miniaturized. For this reason, the actuators 10 can be provided with high density. Moreover, since the actuator 10 can be operated stably in the air, there is no limitation in use.

### Second Embodiment

Hereinafter, there will be explained a second embodiment of the present disclosure.

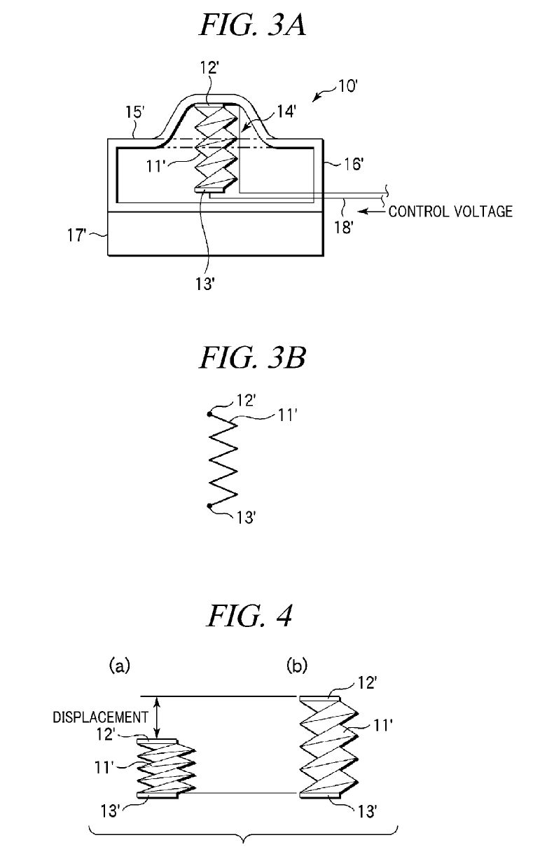

FIGS. 3A and 3B are schematic cross-sectional views of an actuator in accordance with the second embodiment of the present disclosure.

As depicted in FIG. 3A, an actuator 10′ in accordance with the present embodiment includes a main body 14′ having a displacement unit 11′ and electrodes 12′ and 13′; and a displacement transmission unit 15′. The displacement unit 11′ has a plate shape and is made of a mixture of a silicone-containing elastomer as an electrically driven polymer and an ionic liquid. Further, the electrodes 12′ and 13′ are provided on both surfaces of the displacement unit 11′ so as to supply power to the displacement unit 11′. The displacement transmission unit 15′ is provided so as to cover the displacement unit 11′ and displaced in an out-of-plane direction (in a direction perpendicular to a plane) by displacement of the displacement unit 11′.

The displacement unit 11′ has a folded paper form (an origami structure) in which it is alternately folded in a longitudinal direction thereof. When a voltage is not applied, the displacement unit 11′ is in a folded state and a surface of the displacement transmission unit 15 is in a flat state as indicated by a dashed double-dotted line in FIG. 3A. When a control voltage is applied between the electrodes 12′ and 13′, the displacement unit 11′ is displaced (extended) in one direction, e.g. in an upward direction as depicted in FIG. 3A, so that the displacement transmission unit 15′ is displaced in an out-of-plane direction (upward direction). FIG. 3B shows a simplified configuration of the displacement unit 11′.

The displacement transmission unit 15′ is made of resin, such as polyimide, having elasticity in the same manner as the displacement transmission unit 15. When a voltage is not applied to the displacement unit 11′ so that the displacement unit 11′ is in a folded state, the displacement transmission unit 15′ is also in a flat state. When a voltage is applied to the displacement unit 11′ so that the displacement unit 11′ is displaced, the displacement transmission unit 15′ is displaced accordingly in an out-of-plane direction, e.g. in an upward direction in FIG. 3. Thereafter, when the voltage is not applied so that the displacement unit 11′ returns to its folded state, the displacement transmission unit 15′ also returns to its flat state.

The displacement transmission unit 15′ is configured as a part of a container 16′ that accommodates the main body 14′. The container 16′ is fixed to a fixing plate 17′ made of metal such as Cu or Al or a soft material such as resin.

In a pair of the electrodes 12′ and 13′, one is a positive electrode and the other is a negative electrode. A control wire 18′ is connected to these electrodes 12′ and 13′. A certain control voltage is applied to the electrodes 12′ and 13′ via this control wire 18′.

Hereinafter, there will be explained an operation of the actuator 10′ configured as described above.

FIG. 4(a) shows the displacement unit 11′ in a folded state when a voltage is not applied to the electrodes 12′ and 13′. If a voltage is applied to the electrodes 12′ and 13′ in this state, as described in the first embodiment, polarization may be generated. Therefore, ions are distributed non-uniformly in the displacement unit 11′ so that the displacement unit 11′ is deformed to be displaced in one direction (upward direction) as depicted in FIG. 4(b).

Since the actuator 10′ of the present embodiment includes the displacement unit 11′ made of organic materials in the same manner as the first embodiment, the actuator 10′ may be greatly deformed by the application of a voltage. Therefore, the actuator 10′ may have a large amount of stroke. Further, since the actuator 10′ can be operated stably in the air, there is no limitation in use.

Since the displacement unit 11′ is displaced from a folded state to an extended state, it may have a greater stroke as compared with the first embodiment. Further, since the displacement unit 11′ is displaced in a linear motion, it may occupy a smaller footprint as compared with the first embodiment. Therefore, the displacement unit 11′ can be miniaturized. For this reason, the actuator 10′ can be arranged with higher density as compared with the actuator 10 of the first embodiment.

### Third Embodiment

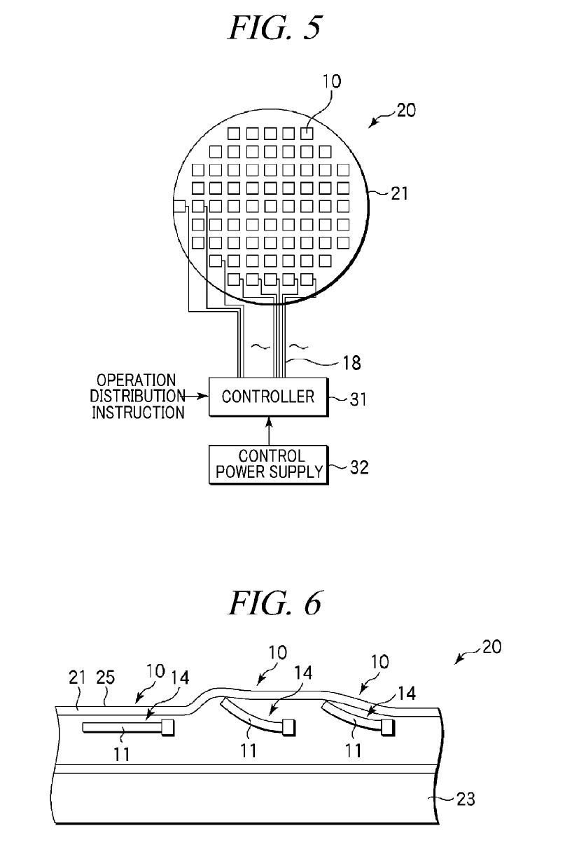

The present embodiment relates to a sheet-shaped actuator including multiple actuators. FIG. 5 is a plane view of a sheet-shaped actuator in accordance with a third embodiment of the present disclosure, and FIG. 6 is a cross-sectional view showing a part thereof.

A sheet-shaped actuator 20 includes a container 21 having a flat surface; multiple main bodies 14 in accordance with the first embodiment arranged with a high density in a planar shape; and a fixing plate 23 made of metal such as Al and Cu. The container 21 is made of resin having elasticity, such as polyimide. Lower surfaces of the main bodies 14 are attached to an inner surface of the container 21. The container 21 is fixed to the fixing plate 23. Further, an upper surface of the container 21 is configured as a common displacement transmission unit 25 of the multiple actuators 10.

The control wire 18 is extended from the electrodes 12 and 13 of each actuator 10. The control wires 18 from all of the actuators 10 are extended to a controller 31. Further, the controller 31 is connected to a control power supply 32. An operation distribution instruction is inputted from a non-illustrated sensor into the controller 31. Based on this instruction, the controller 31 applies a certain control voltage to the multiple actuators 10. As a result, a desired height distribution is formed in the common displacement transmission unit 25.

As described above, since the actuator 10 is miniaturized with a simple configuration, the actuators 10 can be provided with high density. Further, since the actuator 10 has a large amount of stroke, the sheet-shaped actuator 20 of the present embodiment including the multiple actuators 10 is very suitable for a position adjustment sheet or a gap adjustment sheet of a large-sized substrate such as a semiconductor wafer.

### Fourth Embodiment

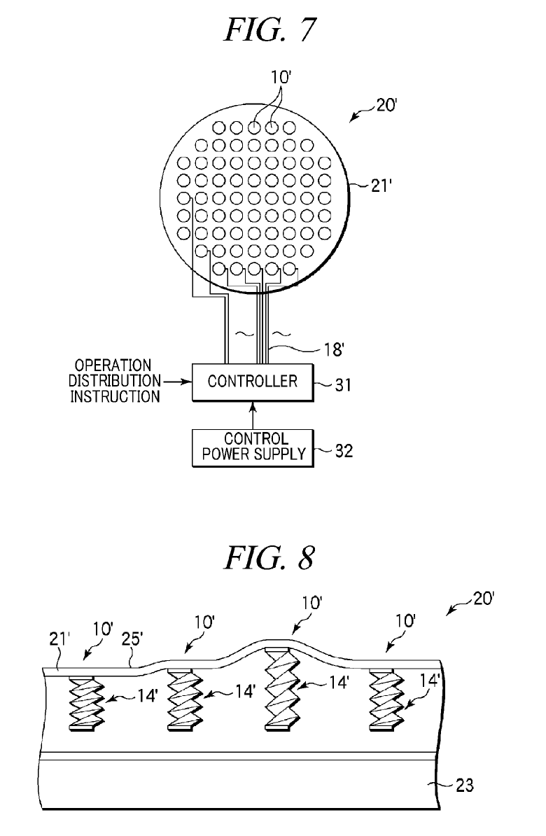

The present embodiment relates to a sheet-shaped actuator including multiple actuators in the same manner as the third embodiment. FIG. 7 is a plane view of a sheet-shaped actuator in accordance with a fourth embodiment of the present disclosure, and FIG. 8 is a cross-sectional view showing a part thereof.

A sheet-shaped actuator 20′ includes a container 21′ having a flat surface; multiple main bodies 14′ in accordance with the second embodiment arranged with a high density in a planar shape; and a fixing plate 23 made of metal such as Al and Cu. The container 21′ is made of resin having elasticity, such as polyimide. Lower surfaces of the main bodies 14′ are attached to an inner surface of the container 21′. The container 21′ is fixed to the fixing plate 23. Further, an upper surface of the container 21′ is configured as a common displacement transmission unit 25′ of the multiple actuators 10′.

The control wire 18′ is extended from the electrodes 12′ and 13′ of each actuator 10′. The control wires 18′ from all of the actuators 10′ are extended to a controller 31 in the same manner as the third embodiment. Further, the controller 31 is connected to a control power supply 32. An operation distribution instruction is inputted from a non-illustrated sensor into the controller 31. Based on this instruction, the controller 31 applies a certain control voltage to the multiple actuators 10′. As a result, a desired height distribution is formed in the common displacement transmission unit 25′.

As described above, since the actuator 10′ is miniaturized with a simple configuration, the actuators 10′ can be provided with high density. Further, since the actuator 10′ has a large amount of stroke, the sheet-shaped actuator 20′ of the present embodiment including the multiple actuators 10′ is very suitable for a position adjustment sheet or a gap adjustment sheet of a large-sized substrate such as a semiconductor.

### APPLICATION EXAMPLE

Hereinafter, there will be explained an application example of the actuators and the sheet-shaped actuator described in the above-described embodiments.

### APPLICATION EXAMPLE OF PROBE DEVICE

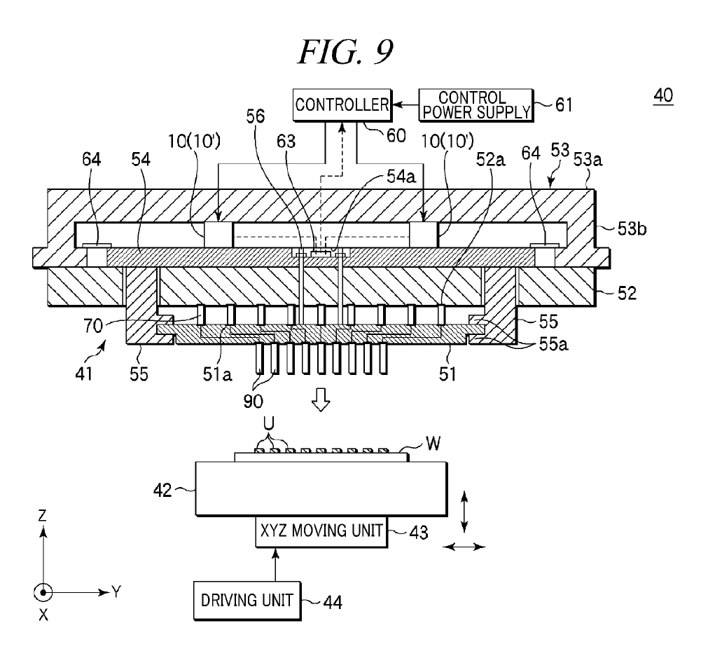

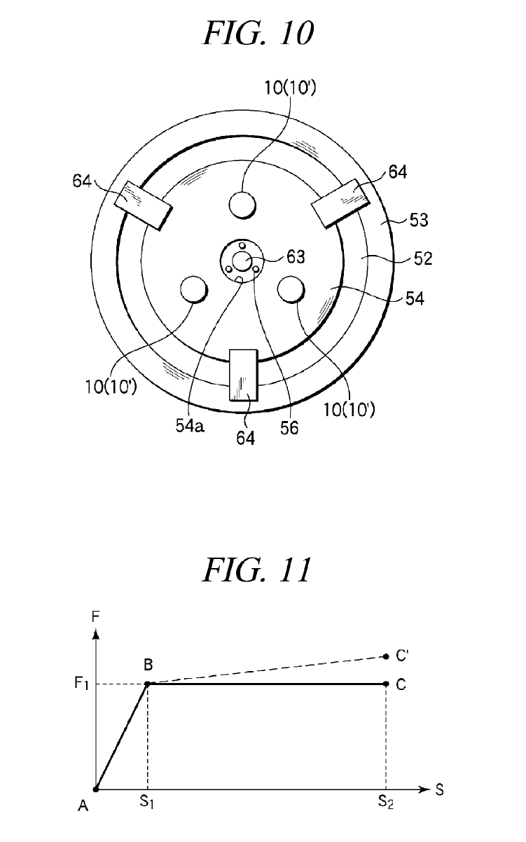

FIG. 9 is a cross-sectional view of a probe device using an actuator in accordance with the first embodiment or the second embodiment as a load control member, and FIG. 10 is a plane view in a vicinity of an upper surface of a connecting member of the probe device shown in FIG. 9.

A probe device 40 is configured to test electrical characteristics of a semiconductor wafer (hereinafter, simply referred to as “wafer”). The probe device 40 includes a probe card 41 and a mounting table 42 for mounting thereon a wafer W as an object to be tested. The probe card 41 is provided above the mounting table 42.

The probe card 41 has a substantially disc shape on the whole. Further, the probe card 41 includes a circuit board 52 provided on an upper surface of a supporting plate 51. The supporting plate 51 is configured to support on the bottom surface thereof contactors (probes) 90 to be in contact with electrode pads U of the wafer W during a test. The circuit board 52 is configured to send an electrical testing signal to the contactors 90.

The circuit board 52 has a substantially disc shape and is electrically connected to a non-illustrated tester. Within the circuit board 52, an electronic circuit configured to transmit an electrical testing signal between the circuit board 52 and the contactors 90 is embedded. The electrical testing signal from the tester is sent to and received from the contactors 90 via the electronic circuit of the circuit board 52. On a lower surface of the circuit board 52, connecting terminals 52a are provided.

On an upper surface of the circuit board 52, a reinforcement member 53 configured to reinforce the circuit board 52 is provided. The reinforcement member 53 includes a main body 53a provided above the circuit board 52 in parallel thereto; and a fixing body 53b, extending downward from an outer periphery of the main body 53a, for fixing an outer periphery of the circuit board 52. The fixing body 53b is protruded toward an inside of the circuit board 52 and extended toward an outside thereof. An outer periphery of the fixing body 53b is held by a non-illustrated holder.

On the upper surface of the circuit board 52, a connecting member 54 is provided in parallel to the circuit board 52. The connecting member 54 is formed in a substantially disc shape having a diameter smaller than that of the circuit board 52 and provided inside the fixing body 53b of the reinforcement member 53. Further, since the connecting member 54 is in contact with the upper surface of the circuit board 52, it can correct flatness of the circuit board 52.

Connecting bodies 55 configured to connect the supporting plate 51 with the connecting member 54 as a single unit is fixed to a lower surface of an outer periphery of the connecting member 54. Each of the connecting bodies 55 is extended in a vertical direction and located at multiple, for example, four positions of an outer periphery of the supporting plate 51.

The connecting bodies 55 penetrate the circuit board 52 in the thickness direction thereof and lower ends of the connecting bodies 55 reach an an outer periphery of the supporting plate 51. Protrusions 55a protruding toward the supporting plate 51 are formed at two vertical positions of the lower portion of each connecting body 55 so as to support the supporting plate 51. The protrusions 55a may be plate springs. In this case, while the outer periphery of the supporting plate 51 is held from a lower side, the supporting plate 51 is pressed toward the circuit board 52. Thus, an electrical contact between the supporting plate 51 and the circuit board 52 can be maintained.

At an upper central area of the connecting member 54, as depicted in FIG. 10, multiple, for example, three bolts 56 are provided. The upper ends of the bolts 56 are engaged in a recess 54a provided at the upper central area of the connecting member 54 as depicted in FIG. 9. The bolts 56 penetrate the circuit board 52 in a thickness direction thereof and the lower ends thereof are fixed to an upper surface of the supporting plate 51. Therefore, the supporting plate 51 may be connected to the connecting member 54 by the connecting bodies 55 and the bolts 56.

On the upper surface of the connecting member 54, the actuators 10 or 10′ of the present embodiment serving as a load control member for controlling a contact load between the contactor 90 and the electrode pad U to be constant are provided. The actuators 10 or 10′ are provided at multiple, for example, three places as depicted in FIG. 10. When viewed from the top, the actuators 10 are arranged at a regular interval along the same circumference with respect to the center of the connecting member 54. Upper surfaces of the actuators 10 or 10′ are in direct contact with the main body 53a of the reinforcement member 53. The actuators or 10′ can generate a certain thrust in a certain direction. Accordingly, the actuators 10 or 10′ can generate a constant load regardless of an application point of the load.

A load measurement device 63 configured to measure a load to the actuator 10 or 10′ is provided in the recess 54a. The load measurement device 63 is connected to a controller 60. The controller 60 is connected to a control power supply 61 and the actuator 10 or 10′. Further, the controller 60 controls a control voltage applied to the actuator 10 or 10′ based on a signal from the load measurement device 63 and controls the thrust of the actuator 10 or 10′ such that the thrust has a constant value regardless of a displacement position (displacement). Therefore, when the contactors 90 are in contact with the electrode pads U during a test, a contact load thereof can be controlled to be a predetermined level. That is, the controller 60 controls a voltage applied to the actuator 10 or 10′ from the control power supply 61 based on a measurement result of the load measurement device 63. Accordingly, even if the contactors 90 are in contact with the electrode pads U at different heights, a contact load between the contactors 90 and the electrode pads U can be controlled to be uniform. The number of the actuators 10 or 10′ is not limited to three but three or more actuators 10 or 10′ may be desirable.

At the outer periphery of the connecting member 54, plate springs serving as elastic members 64 are provided. One end of the each of the plate springs 64 is fixed to the outer periphery of the connecting member 54 and the other end thereof is fixed to the fixing body 53b of the reinforcement member 53. A multiple number of, for example, three plate springs 64 are arranged along a circumference, desirably, in a regular interval. A horizontal position of the supporting plate 51 is fixed by these plate springs 64.

The supporting plate 51 is provided so as to face the mounting table 42 and to be in parallel with the circuit board 52. The supporting plate 51 has a substantially rectangular plate shape. At an upper surface thereof, multiple connecting terminals 51a are provided. The connecting terminals 51a are arranged so as to correspond to the connecting terminals 52a of the circuit board 52.

Between the connecting terminals 51a of the supporting plate 51 and the connecting terminals 52a of the circuit board 52 corresponding to the connecting terminals 51a, multiple intermediate members 70 for electrical connection therebetween are provided. The multiple intermediate members 70 are arranged uniformly on the upper surface of the supporting plate 51. Each of the intermediate members 70 is configured so as to be independently extendible and contractible in a vertical direction. Thus, even when, for example, the contactors 90 are in contact with the electrode pads U at different heights, it is possible to uniformize the distribution of the contact loads between the contactors 90 and the electrode pads through the intermediate members 70.

At a lower surface of the supporting plate 51, the contactors 90 are provided at a smaller pitch than that of the connecting terminals 51a at the upper surface. The number of the contactors 90 located at the lower surface of the supporting plate 51 is the same as that of the connecting terminals 51a arranged to correspond thereto. The corresponding connecting terminal 51a and contactor 90 is connected to each other via a wire within the supporting plate 51. As such, the supporting plate 51 may serve as a pitch adjusting board for controlling a pitch of the connecting terminals 52a of the circuit board 52.

The mounting table 42 is configured to be moved in a horizontal direction and a vertical direction by an XYZ moving unit 43. The XYZ moving unit 43 is driven by a driving unit 44, so that a wafer W mounted on the mounting table 42 can be moved three-dimensionally. Therefore, alignment of the wafer W can be carried out with high accuracy.

In the present example, requirements of the actuator or 10′ are as follows. The actuator 10 or 10′ is operated on conditions that a position of the actuator is an outer diameter of about Φ 100 mm; a thickness of the actuator is about 5 mm or less ±50%; a driving force is about 20 kgf/cm² at each point; an operation temperature is room temperature ±20° C., and an operation speed is seconds to minutes. The actuators described in the first and second embodiments can fully satisfy these requirements.

Hereinafter, there will be explained an operation performed when electrical characteristics of the wafer W are actually tested with the probe device 40 configured as described above.

FIG. 11 is a graph showing a relationship between positional displacement S of the electrode pads U and a load F generated as a contact load between the contactors 90 and the electrode pads U. In FIG. 11, a generated load F is the sum of, for example, weights of movable members such as the contactors 90, the supporting plate 51, the connecting member 54, and the connecting bodies 55 and an initial load of the intermediate members 70. First, when the wafer W is mounted on the mounting table 42, the mounting table 42 is lifted up and each of the electrode pads U of the wafer W is in contact with each of the contactors 90. A relationship, at that time, between the positional displacement S of the electrode pads U and the generated load F is shown as a point A in FIG. 11.

When the electrode pads U continues to be lifted up, the contactors 90 are compressed in a vertical direction by an upwardly applied force. Until the positional displacement of the electrode pad U reaches S₁, i.e. until a generated load reaches F₁, the generated load F is absorbed by the compression of the contactors 90. Therefore, in this case, even if the electrode pads U are lifted up, the supporting plate 51 is not lifted up. Further, the relationship between the positional displacement S of the electrode pads U and the generated load F during this period is shown as a section between points A and B in FIG. 11.

Then, the electrode pads U further continues to be lifted up such that the positional displacement reaches S₂. At that time, the generated load F is transferred to the intermediate members 70 via the supporting plate 51, and further transferred to the actuator 10 or 10′ via the supporting plate 51, the connecting bodies 55, and the connecting member 54. At that time, the supporting plate 51, the connecting bodies 55, and the connecting member 54 are lifted up. At that time, the controller 60 controls a voltage applied to the actuator 10 or 10′ from the control power supply 61 based on a measurement result of the load measurement device 63. Thus, a contact load between the contactors 90 and the electrode pads U can be controlled to be constant. Therefore, while the positional displacement S of the electrode pads U is displaced from S₁ to S₂, the generated load F can be controlled to be F₁.

While the contact load is controlled to be constant, an electrical testing signal is transmitted from the circuit board 52 to each of the electrode pads U on the wafer W through the intermediate members 70, the connecting terminals 51a of the supporting plate 51, and the contactors in sequence. Then, electrical characteristics of a circuit on the wafer W can be tested.

In a conventional probe device, if a probe card is not provided to be in parallel with a mounting table or if a mounting table is not flat, multiple contactors are in contact with electrode pads at different heights and a contact load cannot be distributed uniformly. Therefore, the contactors and the electrode pads are in poor contact with each other. Further, if a horizontal movement of the supporting plate is not controlled, the contactors cannot be properly contacted with the electrode pads, which leads to poor contact therebetween. However, by using an actuator as described above, it may be possible to uniformly control the distribution of the contact load and constantly control the contact load. As a result, the problem of the poor contact can be solved.

Although the applicant has previously developed a method of constantly maintaining a contact load by using a spring instead of an actuator, since a force applied by a spring can vary depending on a compressed length of the spring, a contact load cannot be maintained uniformly in the strict sense. As positional displacement of an electrode pad increases, the contact load tends to be increased (section between points B and C′ in FIG. 11). However, by using the actuator 10 or 10′, as depicted in FIG. 11, a contact load can be maintained constantly.

### APPLICATION EXAMPLE TO PLASMA ETCHING APPARATUS

### (1) APPLICATION EXAMPLE TO FOCUS RING

Herein, there will be explained an example where a sheet-shaped actuator of the present disclosure is used as a gap adjustment sheet of a focus ring provided around a wafer at a mounting table of a plasma etching apparatus.

A plasma etching apparatus includes a chamber; a mounting table mounting thereon a wafer and serving as a lower electrode; and an upper electrode facing the mounting table. In such a plasma etching apparatus, a high frequency electric field is generated between these upper and lower electrodes by applying a high frequency power to the upper electrode or the lower electrode. Then, an etching process is performed on the wafer mounted on the mounting table by plasma of processing gas, which is generated in the high frequency electric field.

FIG. 12 is a cross-sectional view of a mounting table of a plasma etching apparatus using a sheet-shaped actuator of the present disclosure as a gap adjustment sheet of a focus ring.

A mounting table 140 is provided at a bottom area of the chamber via an insulating plate. The mounting table 140 includes a mounting table main body 142 formed in a cylindrical shape having a step-shaped portion. That is, the mounting table main body 142 includes an upper portion 142a of a small diameter and a lower portion 142b of a large diameter. On an upper surface of the upper portion 142a of a small diameter, an electrostatic chuck 144 for attracting a wafer W by an electrostatic force such as a Coulomb force is provided.

Around the upper portion 142a, a circular-ring-shaped focus ring 146 for improving etching uniformity is provided such that a top surface thereof has the same vertical position as that of the wafer W. The focus ring 146 is made of silicon if a target to be etched is made of silicon, and is made of silicon oxide if a target to be etched is an oxide film.

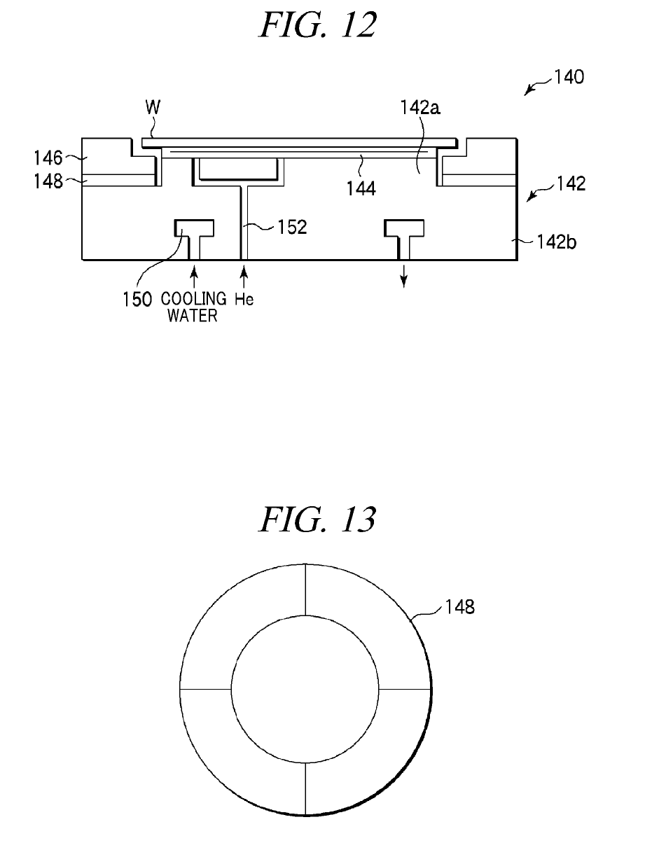

Between the focus ring 146 and a surface of the lower portion 142b, a circular-ring-shaped and sheet-shaped actuator 148 having the same configuration as the sheet-shaped actuator described in the third or fourth embodiment is provided. The sheet-shaped actuator 148 serves as a gap adjustment sheet. By way of example, as depicted in FIG. 13, the sheet-shaped actuator 148 is divided into four portions and controlled to be operated. The sheet-shaped actuator 148 may be controlled to be operated as a whole.

Within the mounting table main body 142, a coolant path 150 is formed. A coolant, for example, cooling water, having a certain temperature is supplied into the coolant path 150 from a non-illustrated chiller unit provided outside, and circulated therein. A processing temperature of the wafer W is controlled by adjusting the temperature of the coolant. Further, a heat transfer gas, for example, a He gas, is supplied between an upper surface of the electrostatic chuck 144 and a rear surface of the semiconductor wafer W from a non-illustrated heat transfer gas supply unit through a gas supply line 152.

In order to perform the etching process in a uniform manner, a top surface of the focus ring 146 need to have the same vertical position as that of the wafer W. However, conventionally, a top surface of the focus ring 146 is etched by sputtering of plasma during the etching process. As a result, etching uniformity in a diametric direction becomes decreased.

Therefore, in the present example, the sheet-shaped actuator 148 having the same basic configuration as described in the third or fourth embodiment is provided below the focus ring 146 as a gap adjustment sheet. The focus ring 146 is lifted up by the sheet-shaped actuator 148 as much as being etched by the sputtering of plasma.

By way of example, in case of a 300 mm wafer, the sheet-shaped actuator 148 may need to have an inner diameter of about 300 mm and an outer diameter of about 500 mm (or about 350 mm); to have a thickness of about 2 mm or less having a variation of ±50% or more; and to have an operation temperature in a range of from about 80° C. to about 200° C.; and to have a thermal conductivity as high as possible (for example, about 1 W/mK). Further, in case of an etching apparatus for etching an oxide film, a withstanding voltage may be about 3000 V, and in case of an etching apparatus for etching polysilicon, a withstanding voltage may be at most about 1000 V. A sheet-shaped actuator having the same basic configuration as described in the third or fourth embodiment can fully satisfy these requirements.

### (2) APPLICATION EXAMPLE TO MOUNTING TABLE

Herein, there will be explained an application example where a sheet-shaped actuator of the present disclosure is used as a shape correction sheet and provided below a wafer at a mounting table of a plasma etching apparatus.

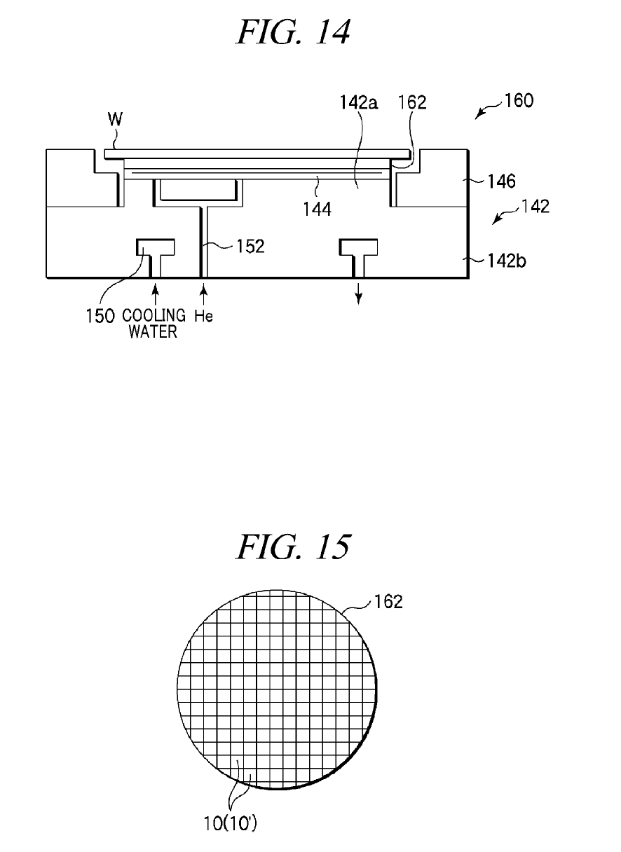

FIG. 14 is a cross-sectional view of a mounting table of a plasma etching apparatus using a sheet-shaped actuator of the present disclosure as a shape correction sheet for correcting a shape of a wafer on the mounting table.

Since a mounting table 160 has the same basic configuration as the mounting table 140, same components will be assigned the same reference numerals and explanations thereof will be omitted. The mounting table 160 includes a disc sheet-shaped actuator 162 having the same basic configuration as described in the third or fourth embodiment between the electrostatic chuck 144 and the wafer W. Although the sheet-shaped actuator 148 is not provided below a focus ring 146 in this example, it may be provided.

The sheet-shaped actuator 162 is configured to correct bending or torsion of the wafer W to restore the wafer W to be in a horizontal state. As depicted in a plane view of FIG. 15, the actuator 10 or 10′ may be arranged per, for example, about 4 cm² with high density.

In order to perform an etching process in a uniform manner, it may be important that the wafer W is maintained to be in a horizontal state without deformation such as bending or torsion. However, practically, the wafer W is easily deformed due to bending or torsion, and, thus, etching uniformity cannot be sufficiently high.

Therefore, in the present example, the sheet-shaped actuator 162 having the same basic configuration as described in the third or fourth embodiment is provided between the wafer W and the electrostatic chuck 144 as a shape correction sheet. The wafer W may be restored to be in a horizontal state by the sheet-shaped actuator 162, and etching uniformity can be increased.

The sheet-shaped actuator 162 may have substantially the same size as the wafer W. Further, desirably, the sheet-shaped actuator 162 may have a thickness of about 2 mm or less having a variation of ±50% or more; an operation temperature in a range of from about 80° C. to about 200° C.; and a thermal conductivity as high as possible. In case of an etching apparatus for etching an oxide film, a withstanding voltage may be about 3000 V, and in case of an etching apparatus for etching polysilicon, a withstanding voltage may be at most about 1000 V. A sheet-shaped actuator having the same basic configuration as described in the third or fourth embodiment can fully satisfy these requirements.

### APPLICATION EXAMPLE TO BAKE APPARATUS OF PHOTORESIST COATING/DEVELOPING APPARATUS

Herein, there will be explained an application example where a sheet-shaped actuator of the present disclosure is used as a gap adjustment sheet for adjusting a gap associated with a wafer in a bake apparatus of a photoresist coating/developing apparatus.

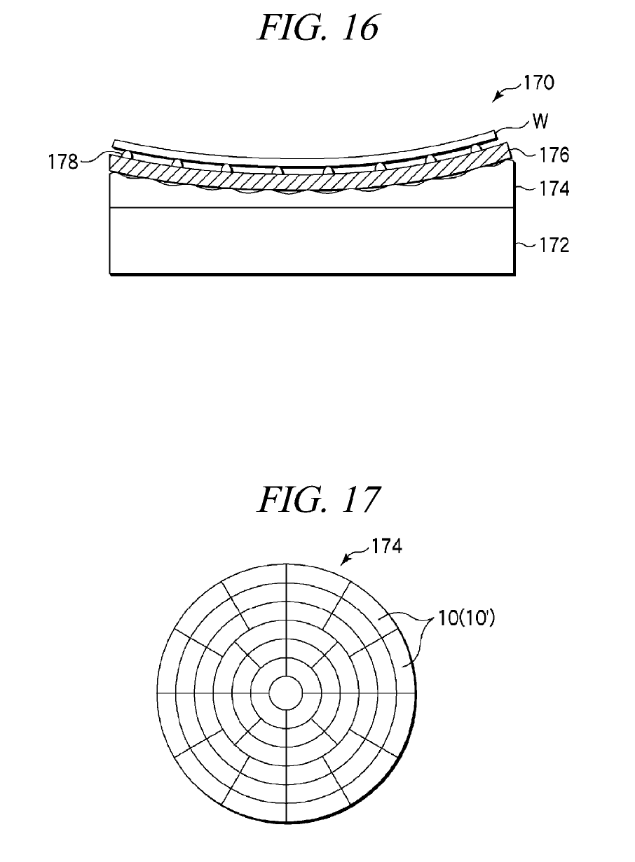

FIG. 16 is a cross-sectional view of a heating unit of a bake apparatus using a sheet-shaped actuator of the present disclosure as a gap adjustment sheet. A heating unit 170 includes a base plate 172 for maintaining the wafer surface in a horizontal position; a sheet-shaped actuator 174 as a gap adjustment sheet provided on the base plate 172; and a film-shaped heater 176 provided on the sheet-shaped actuator 174. On the film-shaped heater 176, multiple wafer supporting pins (proximity pins) 178 are provided. Further, on the wafer supporting pins 178, a wafer is mounted.

The sheet-shaped actuator 174 has the same basic configuration as the sheet-shaped actuator 20 described in the third embodiment or the sheet-shaped actuator 20′ described in the fourth embodiment. The sheet-shaped actuator 174 is configured to constantly adjust a gap between a wafer W and the sheet-shaped heater 176 so as to maintain the wafer W at a constant temperature. As depicted in a plane view of FIG. 17, the actuators 10 or 10′ are provided per, for example, about 14 cm² to about 32 cm² (per about 30 sections to about 50 sections in case of a 300 mm wafer).

In such a bake apparatus, conventionally, a gap between a heating plate on which a wafer is mounted and the wafer is non-uniform due to bending or torsion of the wafer. Accordingly, the wafer cannot be heated in a uniform manner and there may be a difference in temperature within the wafer.

Therefore, in the present example, the sheet-shaped actuator 174 having the same basic configuration as described in the third or fourth embodiment is provided below the sheet-shaped heater 176. Each actuator 10 or 10′ of the sheet-shaped actuator 174 is operated such that a gap may become uniform even when the wafer W is deformed. Thus, a highly uniform temperature uniformity of the wafer can be achieved. To be elaborated, multiple thermocouples for measuring temperatures at multiple points on a rear surface of the wafer W are provided and each actuator 10 or 10′ is operated such that the temperatures of the thermocouples are the same. In such a manner, the sheet-shaped actuator 174 can adjust the gap. Instead of the thermocouples, a sensor in which a pattern of thermocouples is printed may be provided separately and the temperatures may be measured by using the sensor.

The sheet-shaped actuator 174 may have substantially the same size as the wafer. Further, in case of a wafer of about Φ 450 mm, a gap to be adjusted may need to be about 0.4 mm or more. An operation temperature may be in a range of from room temperature to about 180° C. (or from room temperature to about 250° C. or from room temperature to about 300° C.). A sheet-shaped actuator having the same basic configuration as described in the third or fourth embodiment can fully satisfy these requirements.

The coating/developing apparatus includes a cooling apparatus. In the cooling apparatus, a wafer is mounted on a cooling plate via supporting pins. Therefore, in the same manner as the bake apparatus, a gap between the cooling plate and the wafer may be adjusted by a sheet-shaped actuator having the same configuration as described above. Accordingly, temperature uniformity of the wafer can be achieved.

### APPLICATION EXAMPLE TO WAFER CHUCK

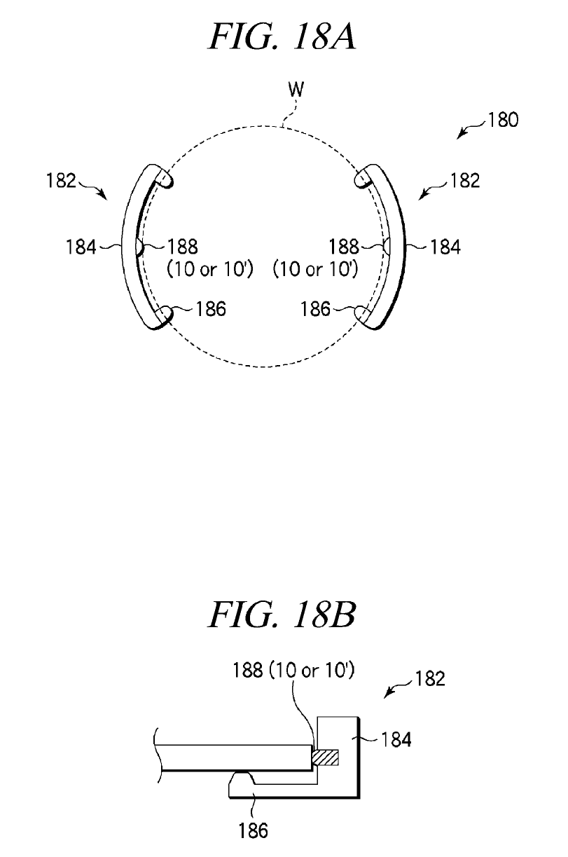

Herein, there will be explained an application example where an actuator of the present disclosure is employed in a wafer chuck for transferring a wafer in a wafer coating/developing apparatus. FIG. 18A is a plane view of the wafer chuck, and FIG. 18B is a side view thereof. A wafer chuck 180 includes a pair of wafer holding arms 182, and a wafer is provided between the wafer holding arms 182 to be held by the wafer holding arms 182.

The entire wafer holding arms 182 are made of wear-resistant resin. Further, the wafer holding arms 182 includes main bodies 184 formed in a circular arc shape corresponding to the wafer W; wafer mounting members 186 protruded inwards from both of the main bodies 184 and configured to mount the wafer W thereon; and edge holders 188 provided at a central portion of the main bodies and configured to hold edges of the wafer W. As the edge holders 188, the actuator 10 or 10′ may be used. When the wafer W is positioned between the wafer holding arms 182, the actuator 10 or 10′ serving as the edge holders 188 may protrude toward the edge of the wafer W. At that time, the actuator 10 or 10′ can hold the wafer W gently. Therefore, particles may not be generated and the wafer W can be held firmly.

Conventionally, the wafer chuck of this kind is affected by a large acceleration of several tens of G in a horizontal direction and 1 G in a vertical direction when the wafer is transferred. As a result, the wafer may be easily deviated. However, by using the actuator 10 or 10′, a wafer having a large diameter can be held firmly without deviation.

The actuator 10 or 10′ serving as the edge holders 188 may need to have an operation temperature in a range of from room temperature to about 100° C.; and an operation speed of several tens of msec and can fully satisfy these requirements.

### APPLICATION EXAMPLE TO MEMS PATTERN WAFER CHUCK

MEMS (Micro Electro Mechanical Systems) are devices in which mechanical components, sensors, actuators, electronic circuits are integrated on a wafer or the like. A wafer having a MEMS pattern cannot be chucked on its entire surface and the wafer can be transferred while being just placed on a transfer arm. Thus, the wafer is easily deviated.

In the present example, there is provided a transfer arm configured to attract and hold a wafer by using a sheet-shaped actuator of the present disclosure.

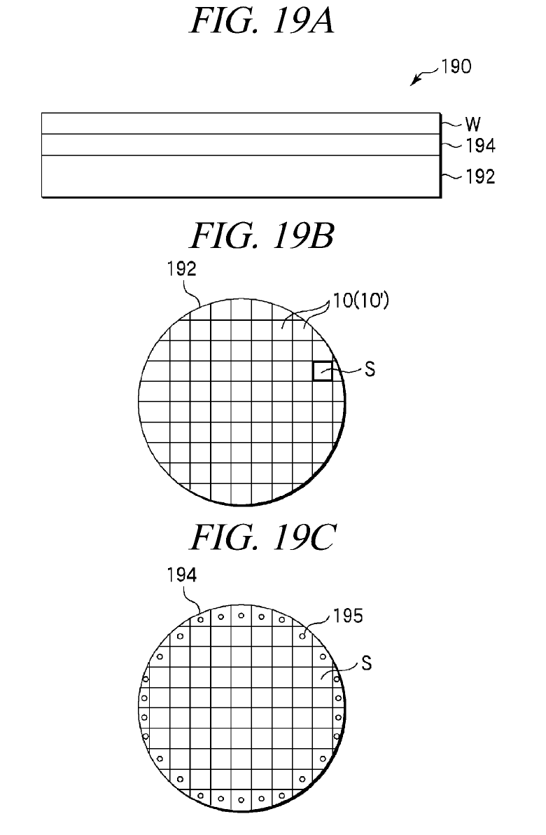

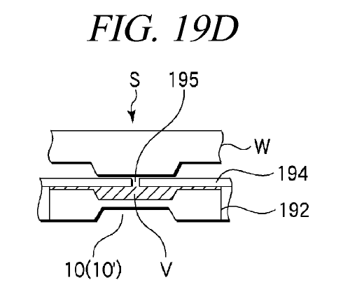

As depicted in FIG. 19A, a transfer arm 190 of the present example includes a sheet-shaped actuator 192 having the same basic configuration as described in the third or fourth embodiment; and a hole spacer 194 provided thereon. On the hole spacer 194, a MEMS pattern wafer W is mounted. In the sheet-shaped actuator 192, as depicted in FIG. 19B, each section S may correspond to each area of, for example, about 1 cm² according to a pattern of the wafer, and an actuator 10 or 10′ is provided in each section S. Further, in the hole spacer 194, as depicted in FIG. 19C, each section S may correspond to each area of, for example, about 1 cm² corresponding to each sheet-shaped actuator 192, and a hole 195 is formed in a certain section S. The holes may be provided in a predetermined part of the sections S. Alternatively, each hole may be provided in all the sections S, and, in such a case, the actuator 10 or 10′ can be selectively ON/OFF controlled. At a section S including a hole 195 of the hole spacer 194, as depicted in FIG. 19D, after the wafer W is mounted, the actuator 10 or 10′ is operated so as to increase a volume of a vacuum space V, i.e. the actuator 10 or 10′ is operated so as to allow the sheet-shaped actuator 192′s thin portion right below the hole 195 to move downwards. In this way, the wafer W is vacuum-attracted via the hole 195. By performing the same operation in the sections S including the holes 195, the wafer W can be attracted and fixed. Thus, the MEMS pattern wafer can be transferred stably at high speed.

The actuator in this case may have an operation temperature in a range of from about −40° C. to about 150° C., and an ON/OFF operation speed of about 1 second or less. The actuator 10 or 10′ in the above-described embodiments can fully satisfy these requirements.

The present disclosure is not limited to the above-described embodiments and can be changed and modified in various ways. By way of example, although a displacement unit of an actuator in the above-described embodiments is formed in a plate shape or an origami structure, the shape of the displacement unit is not limited thereto. Further, although a part of a container that accommodates an actuator is used as a displacement transmission unit, the displacement transmission unit is not limited thereto. The above-described application examples are just provided for illustrations and the present disclosure is not limited to these examples.

What is claimed is:

1. An actuator comprising:
a main body including a displacement unit and an electrode configured to apply a voltage to the displacement unit, the displacement unit being made of a mixture of a silicone-containing elastomer and an ionic liquid, and being displaced by applying a voltage to the electrode; and
a displacement transmission unit configured to be displaced in an out-of-plane direction by displacement of the displacement unit.

2. The actuator of claim 1,
wherein the displacement unit is formed in a plate shape, and when a voltage is applied, one end of the displacement unit is displaced to be bent in one direction.

3. The actuator of claim 1,
wherein the displacement unit is formed in a folded paper form, and when a voltage is applied, the displacement unit is extended in one direction.

4. The actuator of claim 1,
wherein, in a probe device that measures electrical characteristics by bringing contactors into contact with a plurality of electrode pads formed on a substrate, the actuator is provided to serve as a load control member for controlling a contact load between the plurality of electrode pads and the contactors to be constant.

5. The actuator of claim 1,
wherein, in a substrate chuck that transfers a substrate while the substrate is being held by a pair of substrate holding arms, the actuator is provided so as to protrude when the substrate is positioned between the substrate holding arms.

6. A sheet-shaped actuator comprising:
a plurality of main bodies each including a displacement unit and an electrode configured to apply a voltage to the displacement unit, the displacement unit being made of a mixture of a silicone-containing elastomer and an ionic liquid, and being displaced by applying a voltage to the electrode;
a flat container in which the plurality of main bodies are arranged in a planar shape; and
a common displacement transmission unit configured to be displaced in an out-of-plane direction by displacement of each displacement unit of the plurality of main bodies

7. The sheet-shaped actuator of claim 6,
wherein the displacement unit is formed in a plate shape and when a voltage is applied, one end of the displacement unit is displaced to be bent in one direction.

8. The sheet-shaped actuator of claim 6,
wherein the displacement unit is formed in a folded paper form, and when a voltage is applied, the displacement unit is extended in one direction.

9. The sheet-shaped actuator of claim 6,
wherein, in a mounting table that mounts thereon a substrate in a plasma etching apparatus, the sheet-shaped actuator is provided below a focus ring disposed at an outer periphery of the substrate, and when the focus ring is etched by plasma, the sheet-shaped actuator displaces the focus ring upwards as much as being etched.

10. The sheet-shaped actuator of claim 6,
wherein, in a mounting table that mounts thereon a substrate in a plasma etching apparatus, the sheet-shaped actuator is provided so as to support the substrate and displaced so as to correct deformation of the substrate.

11. The sheet-shaped actuator of claim 6,
wherein, in an apparatus that heats or cools a substrate through a heating unit or a cooling unit, respectively, the sheet-shaped actuator is provided and displaced so as to control a gap between the substrate and the heating unit or a gap between the substrate and the cooling unit to be constant.

12. The sheet-shaped actuator of claim 6,
wherein the sheet-shaped actuator is provided in a substrate chuck that attracts and holds a substrate,
the substrate is mounted on the sheet-shaped actuator via a spacer having at least one hole, and
the substrate is vacuum-attracted via the at least one hole of the spacer by displacing the displacement unit of each of the plurality of main bodies at multiple sections.
